(19) United States
(12) Patent Application Publication
(10) Pub. No.: US 2005/0110090 A1
(43) Pub. Date: May 26, 2005

(54) Thin film transistor, method of fabricating the same, and flat panel display using the thin film transistor

(76) Inventors: Jae-Bon Koo, Yongin-si (KR); Sang-Gul Lee, Seoul (KR)

Correspondence Address: MCGUIREWOODS, LLP, 1750 TYSONS BLVD, SUITE 1800, MCLEAN, VA, 22102, US

(21) Appl. No.: 10/994,264

(22) Filed: Nov. 23, 2004

(30) Foreign Application Priority Data
Nov. 25, 2003 (KR) 2003-84242

(51) Int. Cl. H01L 21/00; H01L 27/12; C30B 1/00; H01L 21/36; H01L 21/84; H01L 27/01; H01L 31/0392; H01L 21/20

(52) U.S. Cl. 257/347; 438/151

(57) ABSTRACT

A thin film transistor with a GOLDD structure may include an active layer formed on an insulating substrate including source/drain regions and a channel region. A gate insulating film may be formed on the active layer and a gate electrode may be formed on the gate insulating film. The gate electrode may include a first gate pattern and a second gate pattern formed at sides of the first gate pattern. The source/drain regions may each have an LDD region, and the LDD regions may overlaps-the gate electrode.

### CROSS-REFERENCE TO RELATED APPLICATION

This application claims the benefit of Korea Patent Application No. 2003-84242 filed on Nov. 25, 2003, which is hereby incorporated by reference in its entirety.

### BACKGROUND OF THE INVENTION

(a) Field of the Invention

The present invention relates to a thin film transistor (TFT), a method for fabricating the TFT and a flat panel display using the TFT. More particularly, it relates to a TFT having a gate overlapped lightly doped drain (GOLDD) structure, its method of manufacture, and a flat panel display incorporating it.

(b) Description of the Related Art

An active-matrix flat panel display using a TFT as a switching element may include pixel-driving TFTs formed in and driving the pixels. It may also include driving-circuit is TFTs driving the pixel-driving TFTs and transmitting a signal to a scan line (gate line) and a signal line (data line).

A polycrystalline silicon TFT may be fabricated at a temperature similar to that for fabricating an amorphous silicon TFT due to the advance of crystallization technology using laser. A polycrystalline silicon TFT may allow electrons or holes to have high mobility as compared with the amorphous silicon TFT. Additionally, a complementary metal-oxide semiconductor (CMOS) TFT having n- and p-channels can be made using polycrystalline silicon. Thus polycrystalline silicon can be used to form both the pixel-driving TFTs and the driving-circuit TFTs on a large-sized insulating substrate.

An n-channel metal oxide semiconductor (NMOS) TFT generally uses phosphorus (P) as a dopant. Phosphorus has a greater atomic weight than boron (B) generally used in a p-channel metal oxide semiconductor (PMOS) TFT. Thus, the silicon crystal lattice may become damaged at a predetermined region and the damaged region may not be completely recoverable during the sequential activating process.

Such a damaged region may reduce the mobility of electrons. Mobility is reduced because of hot carrier stress that occurs when accelerated electrons flow across a gate insulating film or a metal-oxide semiconductor (MOS) interface between the source and the drain. Therefore, the damaged region may have a negative effect on circuit operation of the flat display panel, and may increase the off-current of the TFT.

To solve the foregoing problems, various structures, such as an off-set structure, a lightly doped drain (LDD) structure, and the like have been proposed. In an off-set structure, an off-set region is provided to form an imperfect doping region on a predetermined region between the gate and the source/drain regions. In an LDD structure, an LDD is formed by lowering the doping concentration applied to a predetermined region between the source and drain regions. Thus the off-current is decreased and the reduction in on-current is minimized.

However, because low temperature polysilicon (LTPS) technology is highly integrated, the conventional off-set and LDD structures produce limited enhancement of the reliability of a short channel device. To overcome the limit, a thin film transistor with a gate overlapped lightly doped drain (GOLDD) structure was created.

FIGS. 1A, 1B, 1C, and 1D are cross-sectional views for illustrating a fabrication process of a conventional thin film transistor with a GOLDD structure.

As shown in FIG. 1A, a buffer layer 110 may be formed on an insulating substrate 100, and then an amorphous silicon film may be deposited on the buffer layer 110 and crystallized into a polycrystalline silicon film. Thereafter, an active layer 120 may be formed by patterning the polycrystalline silicon film.

After the active layer 120 is formed, a gate insulating film 130 may be formed on substantially an entire surface of the insulating substrate 100 formed with the active layer 120.

After the gate insulating film 130 is formed, a first photoresist pattern 140 may be formed for doping low-concentration impurities having a predetermined conductive type (e.g., for LDD doping).

After the first photoresist pattern 140 is formed, the low-concentration impurities may be doped using the first photoresist pattern 140 as a mask, so that low-concentration source/drain regions 123S and 123D may be formed on the active layer 120. Then, a region between the low-concentration source/drain regions 123S and 123D may be used as a channel region 121 of the thin film transistor.

As shown in FIG. 1B, after the low-concentration source/drain regions 123S and 123D are formed on the active layer 120 through low-concentration doping, the first photoresist pattern 140 may be removed, and a gate electrode material film 150 may be formed on the gate insulating film 130. Then, a second photoresist pattern 160 may be formed to aid in forming a gate electrode.

The second photoresist pattern 160 may be formed partially overlapping the low-concentration source/drain regions 123S and 123D. Further, the width of the overlapped region may be limited to 0.5 μm or more depending on resolution of a stepper.

As shown in FIG. 1C, a gate electrode 155 may be formed by patterning the gate electrode material film 150, using the second photoresist pattern 160 as the mask. Here, the gate electrode 155 may be formed partially overlapping the respective low-concentration source/drain regions 123S and 123D.

After the gate electrode 155 is formed to overlap the respective low-concentration source/drain regions 123S and 123D, high-concentration impurities are doped onto the active layer 120 through the gate electrode 155 used as the mask, thereby forming high-concentration source/drain regions 125S and 125D.

As shown in FIG. 1D, an interlayer insulating film 170 having contact holes 171, 175 through which the high-concentration source/drain regions 125S and 125D are partially exposed may be formed on the entire surface of the insulating substrate 100 with the gate electrode 155. Then, source/drain electrodes 181, 185 may be formed in electrical connection with the high-concentration source/drain regions 125S and 125D through the contact holes 161, 165. This may complete a thin film transistor with a GOLDD structure.

However, in a conventional thin film transistor with the GOLDD structure, it may be difficult to reduce the low-concentration source/drain regions overlapping the gate electrode. In particular, it may be difficult to reduce the width of an LDD range to have a width of 0.5 μm or less because of the resolution of the stepper.

Further, in the conventional thin film transistor with the GOLDD structure, the low-concentration impurities may be doped using a photoresist mask and then the high-concentration impurities may be doped after forming the gate electrode. Thus an additional mask is used for doping the low-concentration impurities. Accordingly, it may be difficult to avoid misaligning the gate electrode.

### SUMMARY OF THE INVENTION

The present invention provides a thin film transistor with a GOLDD structure, a method of fabricating the same, and a flat panel display using the same. In such a thin film transistor the gate electrode may be formed by a gate pattern and a second gate pattern formed at sides of the gate pattern. Thus the width of an LDD region can be easily adjusted and defective alignment of the gate electrode can be prevented.

The present invention may provide a thin film transistor including an active layer formed on an insulating substrate and having source/drain regions and a channel region. The thin film transistor may also include a gate insulating film formed on the active layer and a gate electrode formed on the gate insulating film. The gate may include a first gate pattern and a second gate pattern formed at sides of the first gate pattern. The source/drain regions may each have an LDD region, and the LDD region may overlaps the gate electrode.

The second gate pattern can have a tapered angle. Preferably, the second gate pattern may be patterned by anisotropic etching so as to have the tapered angle.

The present invention also may provide a method of fabricating a thin film transistor. This method may include the steps of: forming an active layer on an insulating substrate; forming a gate insulating film on the active layer; forming a first gate pattern on the gate insulating film; lightly doping the active layer (using the first gate pattern as a mask); forming a gate electrode of the first gate pattern and a second gate pattern formed at sides of the first gate pattern; and forming source/drain regions by highly doping the active layer (using the gate electrode as the mask). The source/drain regions may each have an LDD region, and the LDD regions may overlaps the gate electrode.

### BRIEF DESCRIPTION OF THE DRAWINGS

FIGS. 1A, 1B, 1C, and 1D are cross-sectional views for illustrating a fabrication process of a conventional thin film transistor with a GOLDD structure.

FIGS. 2A, 2B, 2C, and 2D are cross-sectional views for illustrating a fabrication process of a thin film transistor with a GOLDD structure according to a first embodiment of the present invention.

FIGS. 3A, 3B, 3C, and 3D are cross-sectional views for illustrating a fabrication process of a thin film transistor with a GOLDD structure according to a second embodiment of the present invention.

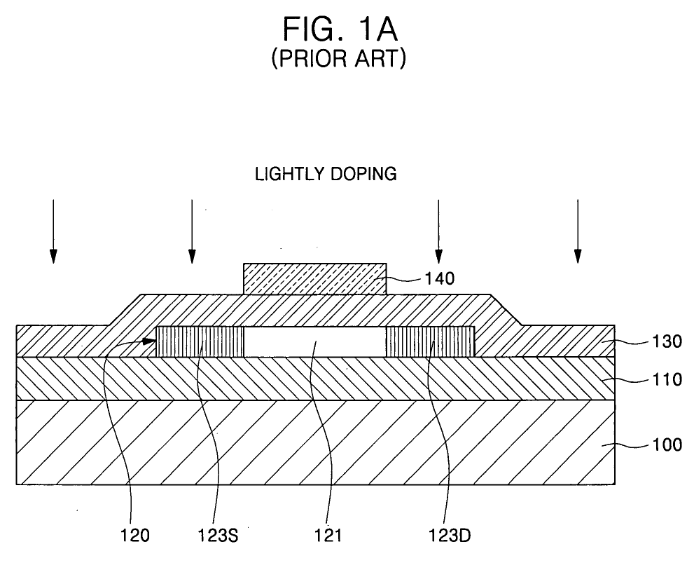

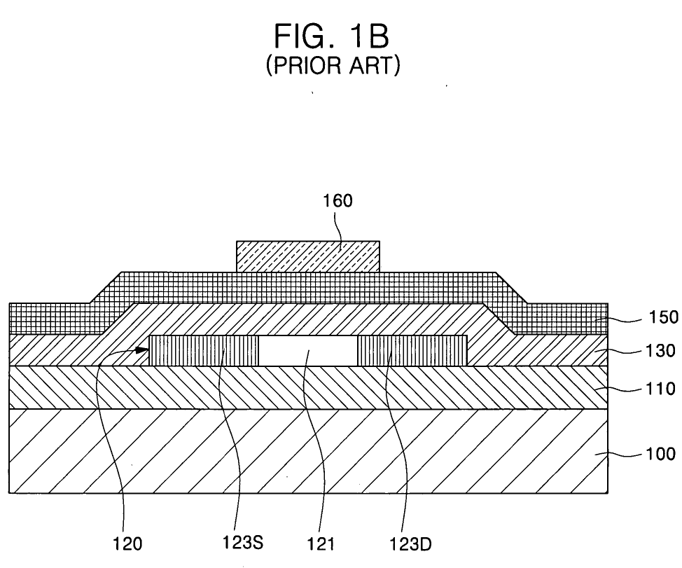

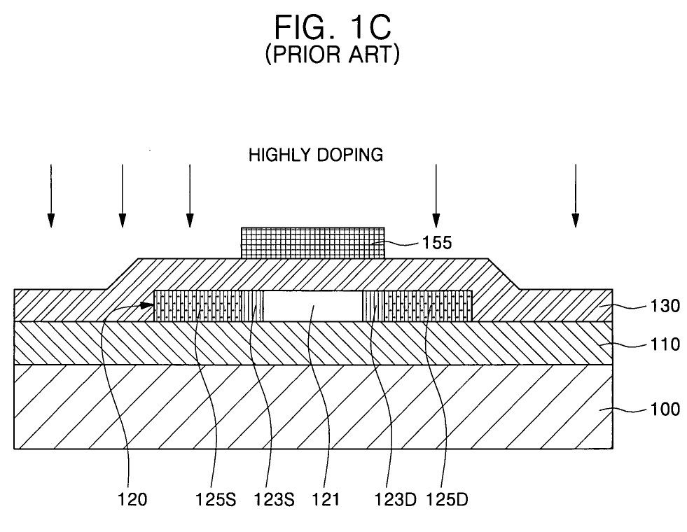

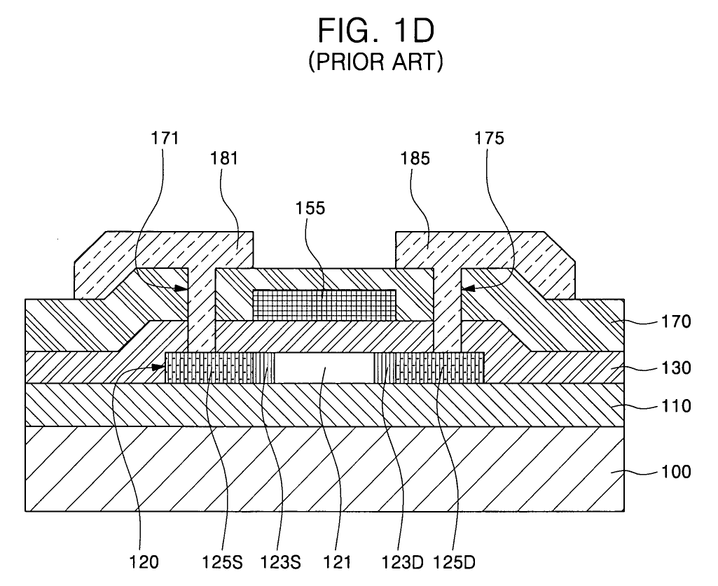

### DETAILED DESCRIPTION OF THE INVENTION

The present invention will now be described more fully with reference to the accompanying drawings, in which preferred embodiments of the invention are shown. This invention may, however, be embodied in different forms and should not be construed as limited to the embodiments set forth herein. In the drawings, the thickness of layers and regions are exaggerated for clarity. Like numbers refer to like elements throughout the specification.

(First Embodiment)

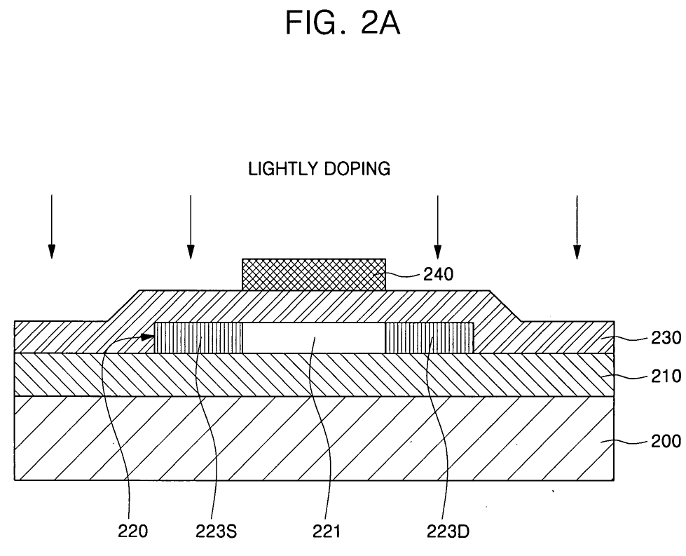

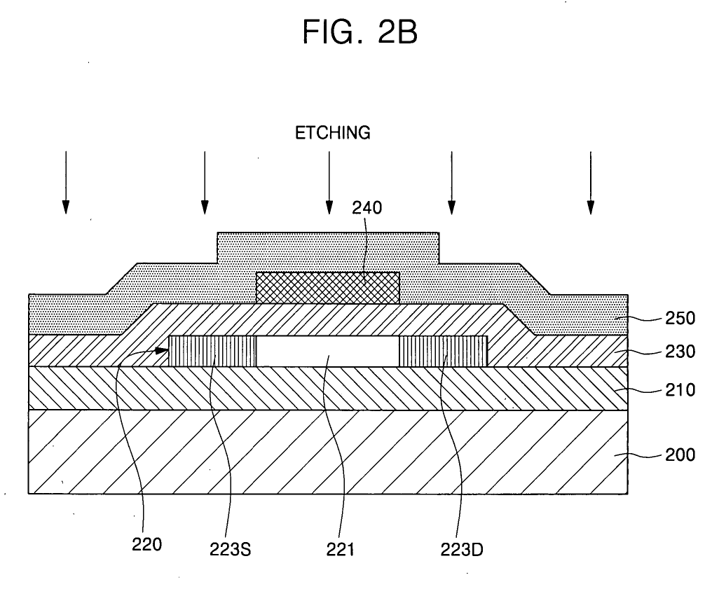

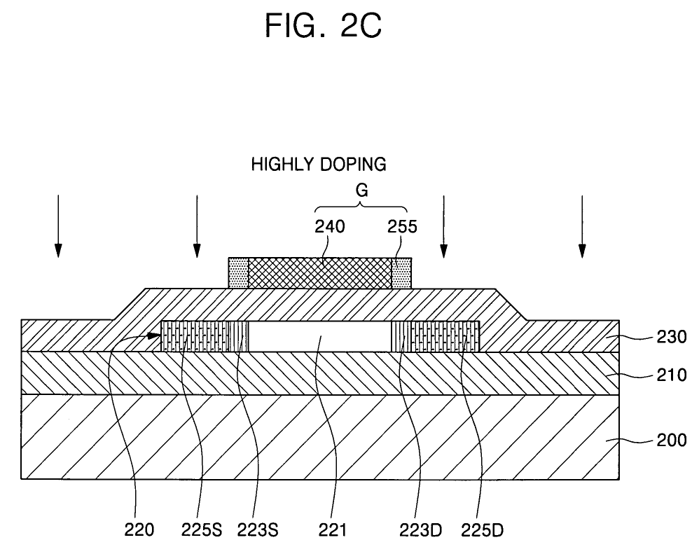

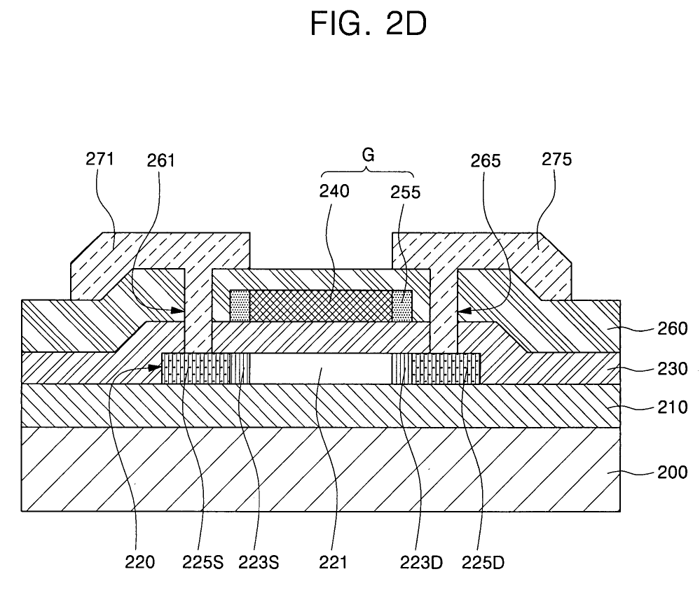

FIGS. 2A, 2B, 2C, and 2D are cross-sectional views for illustrating a fabrication process of a thin film transistor with a GOLDD structure according to a first embodiment of the present invention.

A thin film transistor with a GOLDD structure according to a first embodiment of the present invention has a structure in which a gate electrode may be formed using a first gate pattern and a second gate pattern formed at sides of the gate pattern. This gate electrode may overlap an LDD region as a low-concentration doping region provided in an active layer.

As shown in FIG. 2A, a buffer layer (diffusion barrier) 210 may be formed on an insulating substrate 200 by plasma enhanced chemical vapor deposition (PECVD), low-pressure chemical vapor deposition (LPCVD), sputtering method, or the like. The buffer layer (diffusion barrier) 210 may help to prevent impurities such as a metal ion or the like from being diffused into and infiltrating the active layer (which may be made of amorphous silicon).

After the buffer layer 210 is formed, an amorphous silicon film may be deposited on the buffer layer 210 by PECVD, LPCVD, sputtering, or the like. Then, a dehydrogenation process is performed in a vacuum furnace. In certain deposition techniques (such as, for example, sputtering) the dehydrogenation process may be omitted.

Thereafter, a crystallization process of applying high energy to the amorphous silicon film may be performed to crystallize the amorphous silicon, thereby forming a polycrystalline silicon film. Preferably, excimer laser annealing (ELA), metal induced crystallization (MIC), metal induced lateral crystallization (MILC), sequential lateral solidification (SLS), solid phase crystallization (SPC), or the like can be used as the crystallization process.

After the polycrystalline silicon film is formed, an active layer 220 may be formed by patterning the polycrystalline silicon film.

Thereafter, a gate insulating film 230 may be deposited on the active layer 220, and a first conductive metal film may be deposited on the gate insulating film 230. Then, a first gate pattern 240 may be formed by patterning the conductive metal film.

After the first gate pattern 240 is formed, impurities having a predetermined conductivity type may be lightly doped using the first gate pattern 240 as a mask. Thus, a lightly doped drain (LDD) doping may be performed using the first gate pattern 240 as the mask. Consequently, low-concentration source/drain regions 223S and 223D may be formed. A region between the low-concentration source/drain regions 123S and 123D may function as a channel region 221 of the thin film transistor.

As shown in FIG. 2B, after the low-concentration source/drain regions 223S and 223D are formed, a second conductive material film 250 may be formed on the entire surface of the insulating substrate 200 formed with the first gate pattern 240 so as to form a second gate pattern at sides of the first gate pattern 240.

As shown in FIG. 2C, the second gate pattern 255 may be formed at the sides of the first gate pattern 240 by etching the second conductive material film 250, thereby forming a gate electrode G with both the first gate pattern 240 and the second gate pattern 255 formed at the sides of the first gate pattern 240.

The second gate pattern 255 may be used (in combination with the first gate pattern 240) as a mask for the following high doping. The second gate pattern 255 accordingly determines the width of the LDD region. Therefore, the second gate pattern 255 preferably may be about 2 μm or less wide, and more preferably about 1 μm or less wide.

After the gate electrode G is formed with both the first gate pattern 240 and the second gate pattern 255, the highly concentrated doping may be performed on the active layer 220 using the gate electrode G as a mask. This may form the high-concentration source/drain regions 125S and 125D.

The low-concentration source/drain regions 223S and 223D provided under the second gate pattern 255 formed at the sides of the first gate pattern 240 may not be highly doped because they are masked by the second gate pattern 255. Thus the low-concentration source/drain regions 223S and 223D may remain in the low-concentration doped state and may function as the LDD region. Thus, the gate electrode G may overlaps the lightly doped regions 223S and 223D (overlaps the LDD region), thereby forming the GOLDD structure. Here, the LDD region is formed under the second gate pattern 255 formed at the sides of the first gate pattern 240.

Further, the width of the LDD region of the GOLDD structure may be determined by the width of the second gate pattern 255 formed at the sides of the first gate pattern 240. Thus, the width of the LDD region formed overlapping the gate electrode G may be narrower than the width of the second gate pattern 255 formed at the sides of the first gate pattern 240. That is, the LDD region is preferably about 2 μm or less wide, and more preferably about 1 μm or less wide.

As shown in FIG. 2D, after the high-concentration source/drain regions 225S and 225D are formed, an interlayer insulating film 260 may be formed on the entire surface of the insulating substrate 200 and may be patterned to have contact holes 261 and 265 through which the high-concentration source/drain regions 225S and 225D are partially exposed.

After the contact holes 261 and 265 are formed, a predetermined conductive film may be deposited on the entire surface of the insulating substrate 200 and patterned to form source/drain electrodes 271 and 275 that may be electrically connected to the high-concentration source/drain regions 225S and 225D. Thus, a thin film transistor with the GOLDD structure may be completed.

(Second Embodiment)

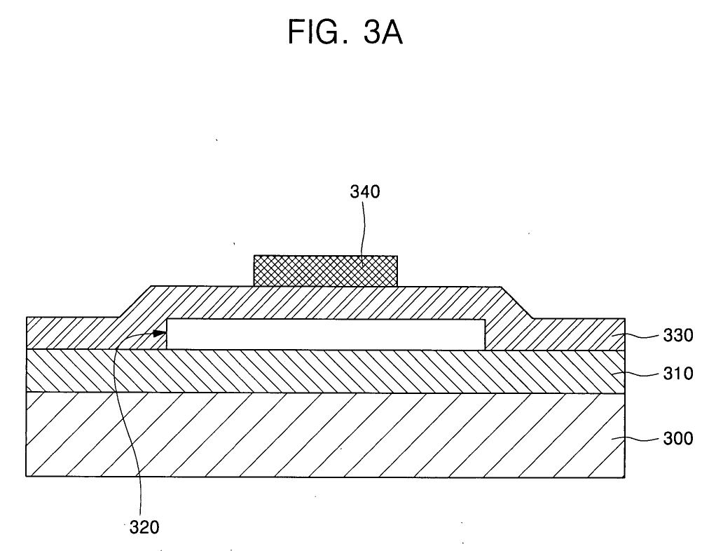

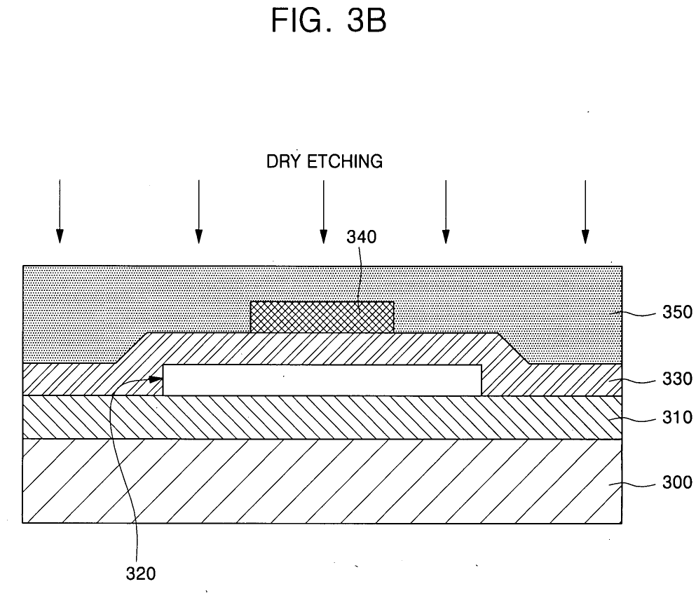

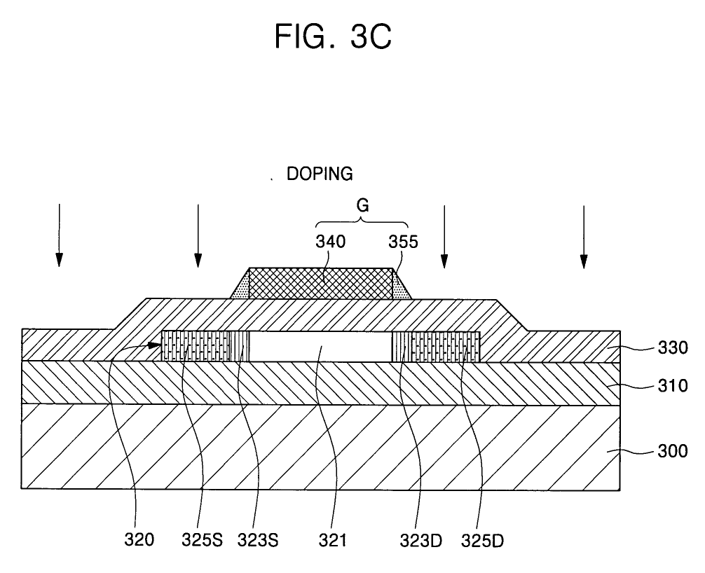

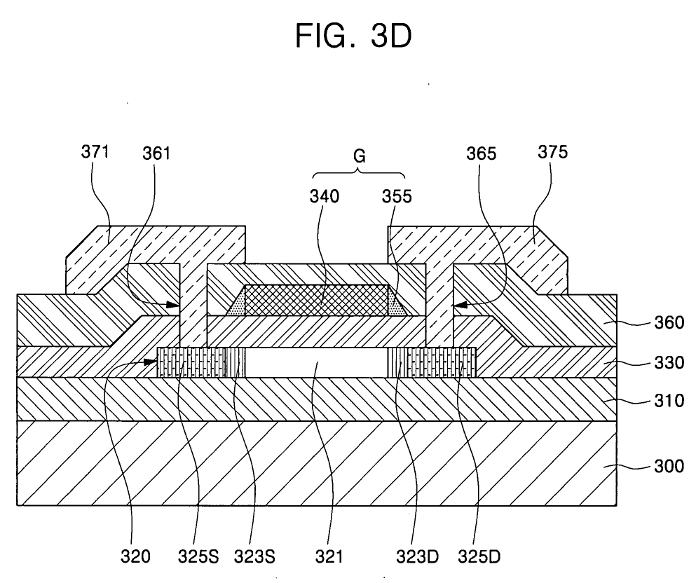

FIGS. 3A, 3B, 3C, and 3D are cross-sectional views for illustrating a fabrication process of a thin film transistor with a GOLDD structure according to a second embodiment of the present invention.

A thin film transistor with a GOLDD structure according to a second embodiment of the present invention may be structurally similar to that of the first embodiment, but different with respect to the structure of the second gate pattern. That is, according to the second embodiment, the second gate pattern 355 formed at sides of the first gate pattern 340 is tapered.

As shown in FIG. 3A, an active layer 320 may be formed on an insulating substrate 300 with a buffer layer 310.

Then, a gate insulating film 330 may be formed on the insulating substrate 300 with the active layer 320, and a first gate pattern 340 may be formed on the gate insulating film 330.

As shown in FIG. 3B, after the first gate pattern 340 is formed, a conductive material film 350 may be formed on the entire surface of the insulating substrate 300 with the first gate pattern 340.

As shown in FIG. 3C, after the conductive material film 350 is formed, the second gate pattern 355 having a tapered angle may be formed at the sides of the first gate pattern 340 by etching the conductive material film 350. One suitable type of etching may be anisotropic etching such as dry etching. Thus, a gate electrode G with both the first gate pattern 340 and the second gate pattern 355 having the tapered angle may be formed.

Here, the tapered second gate pattern 355 preferably is about 2 μm or less wide, and more preferably about 1 μm or less wide.

After the gate electrode G is formed with both the first gate pattern 340 and the tapered second gate pattern 355 is formed at the sides of the first gate pattern 340, predetermined impurities may be doped using the gate electrode G as a mask.

A portion of the active layer 320, which is not covered with the gate electrode G during the doping, may function as source/drain regions 325S and 325D. Conversely, a portion of the active layer 320 under the tapered second gate pattern may function as low-concentration source/drain regions 323S and 323D, thereby being used as the LDD region. Thus, the GOLDD structure is formed in which the gate electrode G overlaps the LDD region.

Similarly to the first embodiment, the LDD region of the GOLDD structure may be determined by the width of the tapered second gate pattern 355 formed at the sides of the first gate pattern 340. Thus the width of the LDD region formed overlapping the gate electrode G may be narrower than the width of the tapered second gate pattern 355 formed at the sides of the first gate pattern 340.

As shown in FIG. 3D, an interlayer insulating film 360 may be formed on the entire surface of the insulating substrate 300. The interlayer insulating film 360 may have contact holes 361 and 365 through which the high-concentration source/drain regions 325S and 325D may be partially exposed. Then, a predetermined conductive film may be deposited and patterned to form source/drain electrodes 371 and 375 that may be electrically connected to the high-concentration source/drain regions 325S and 325D. Thus a thin film transistor with GOLDD structure may be completed.

In the second embodiment, the second gate pattern 355 having the tapered angle may be formed, and then the doping may be performed. Thus, the GOLDD structure in which the LDD region overlaps the gate electrode G may be formed. Similarly, the low-concentration doping may be performed after forming the first gate pattern 340.

As described above, in a thin film transistor with the foregoing GOLDD structure, there is no need for an additional mask for the light doping. Additionally, because of its function as a mask, the gate electrode G may be prevented from defective alignment with respect to the LDD regions.

Also, because the GOLDD structure may be formed using the gate electrode G formed by both the first gate patterns 240, 340 and the second gate patterns 255, 355, the width of the LDD region can be adjusted by the width of the second gate patterns 255, 355. Hence, it may be possible to form an LDD region about 2 μm or less wide, and preferably about 1 μm or less wide.

Further, a method of fabricating an active matrix flat panel display such as an active matrix liquid crystal display or an active matrix organic electroluminescent display can be implemented using the thin film transistor with the foregoing GOLDD structure, thereby providing the active matrix flat panel display.

While the present invention has been described with reference to particular embodiments, it should be understood that the disclosure has been made for purpose of illustrating the invention by way of examples and is not intended to limit the scope of the invention.

1. A thin film transistor, comprising:
an active layer formed on an insulating substrate and having source/drain regions and a channel region;
a gate insulating film formed on the active layer; and
a gate electrode formed on the gate insulating film, and comprising a first gate pattern and a second gate pattern formed at sides of the first gate pattern,
wherein each of the source/drain regions comprises an LDD region, and the LDD regions overlap the gate electrode.

2. The thin film transistor of claim 1, wherein the second gate pattern has a tapered angle.

3. The thin film transistor of claim 2, wherein the tapered angle is created by anisotropic etching.

4. The thin film transistor of claim 1, wherein the second gate pattern is about 2 μm or less wide.

5. The thin film transistor of claim 1, wherein the second gate pattern is about 1 μm or less wide.

6. The thin film transistor of claim 1, wherein the LDD region lies under the second gate pattern.

7. The thin film transistor of claim 1, wherein the LDD region is narrower than the second gate pattern.

8. The thin film transistor of claim 1, wherein the LDD region is about 2 μm or less wide.

9. The thin film transistor of claim 1, wherein the LDD region is about 1 μm or less wide.

10. A method of fabricating a thin film transistor, comprising:
forming an active layer on an insulating substrate;
forming a gate insulating film on the active layer;
forming a first gate pattern on the gate insulating film;
lightly doping the active layer, using the first gate pattern as mask;
forming a second gate pattern formed at sides of the first gate pattern, wherein the first gate pattern and the second gate pattern taken together form a gate electrode; and
highly doping the active layer, using the gate electrode as mask,
wherein highly doping creates source/drain regions, the source/drain regions have LDD regions, and the LDD regions overlap the gate electrode.

11. The method of claim 10, wherein forming the second gate pattern comprises:
forming a conductive material film on substantially an entire surface of the insulating substrate having the first gate pattern; and
etching the conductive material film.

12. The method of claim 10, wherein the second gate pattern is about 2 μm or less wide.

13. The method of claim 10, wherein the second gate pattern is about 1 μm or less wide.

14. The method of claim 10, wherein the LDD region lies under the second gate pattern.

15. The method of claim 10, wherein the LDD region is narrower than the second gate pattern.

16. The method of claim 10, wherein the LDD region is about 2 μm or less wide.

17. The method of claim 16, wherein the LDD region is about 1 μm or less wide.

18. A method for fabricating a thin film transistor, comprising:
forming an active layer on an insulating substrate;
forming a gate insulating film on the active layer;
forming a first gate pattern on the gate insulating film;
forming a second gate pattern at sides of the first gate pattern, wherein the second gate pattern has a tapered angle; and
doping on the active layer, using the gate electrode as a mask,
wherein doping creates source/drain regions that each have an LDD region, and the LDD regions overlaps the gate electrode.

19. The method of claim 18, wherein forming the second gate pattern comprises:
forming a conductive material film on substantially an entire surface of the insulating substrate having the first gate pattern; and
etching the conductive material film by anisotropic etching.

20. The method of claim 18, wherein the second gate pattern is about 2 μm or less wide.

21. The method of claim 20, wherein the second gate pattern is about 1 μm or less wide.

22. The method of claim 18, wherein the LDD region is formed during the doping.

23. The method of claim 18, wherein the LDD is narrower than the second gate pattern.

24. The method of claim 18, wherein the LDD region is about 2 μm or less wide.

25. The method of claim 24, wherein the LDD region is about 1 μm or less wide.

26. An active matrix flat panel display using a thin film transistor, wherein the thin film transistor comprises:
an active layer formed on an insulating substrate and having source/drain regions and a channel region;
a gate insulating film formed on the active layer; and
a gate electrode formed on the gate insulating film, and comprising a first gate pattern and a second gate pattern formed at sides of the first gate pattern,
wherein each of the source/drain regions comprises an LDD region, and the LDD regions overlap the gate electrode.

27. The active matrix flat panel display of claim 26, wherein the flat panel display is a liquid crystal display or an organic electroluminescent display.
